(19) United States
(12) Patent Application Publication
(10) Pub. No.: US 2011/0293847 A1
(43) Pub. Date: Dec. 1, 2011

(54) Particle-Beam Induced Processing Using Liquid Reactants

(76) Inventor: Jeffrey Todd Hastings, Lexington, KY (US)

(21) Appl. No.: 12/789,457

(22) Filed: May 28, 2010

(51) Int. Cl. C23F 17/00; C23C 14/14; C23C 14/06

(52) U.S. Cl. 427/524; 427/523; 427/527; 427/531

(57) ABSTRACT

A system or method of charge particle beam induced materials processing is disclosed. A charged particle beam (electron or ion) is focused at the interface of a substrate and a bulk liquid. The beam induces a localized chemical reaction that results in deposition or etching of deterministic micro- or nano-scale structures. The bulk liquid reactants permit the deposition and etching of metals, semiconductors, and insulators. A charged particle transparent membrane separates the liquid reactant from the vacuum chamber in which the beam is transmitted. In many cases, bulk liquid reactants permit processing of materials with much higher purity that of the prior art and permit processing of materials previously unavailable in charged particle beam processes.

### REFERENCE CITED

### Patents

U.S. Pat. No. 7,329,361 Method and apparatus for fabricating or altering microstructures using local chemical Alterations Guha, et al. Feb. 12, 2008
20070065822 Substrates for spatially selective micron and nanometer scale deposition and combinatorial modification and fabrication Hastwell, et al. Mar. 22, 2007
20060228634 Beam-induced etching Bret, et al. Oct. 12, 2006
20040033679 Patterning of nanostructures Jacobson, et al. Feb. 19, 2004
U.S. Pat. No. 6,319,566 Method of molecular-scale pattern imprinting at surfaces Polanyi, et al. Nov. 20, 2001
JP 06102656 A Photomask forming method Tadayoshi Apr. 15, 1994
U.S. Pat. No. 4,615,765 Self-registered, thermal processing technique using a pulsed heat source Levinson, et al. Oct., 7, 1986
U.S. Pat. No. 4,566,937 Electron beam enhanced surface modification for making highly resolved structures Pitts Jan. 28, 1986
U.S. Pat. No. 4,518,456 Light induced etching of InP by aqueous solutions of H3PO4 Bjorkholm May 21, 1985

### Other Publications

Schossler, C.; Kaya, A.; Kretz, J.; Weber, M.; Koops, H. W. P. Microelectron. Eng. 1996, 30, 471-474.
Yang, X.; Simpson, M. L.; Randolph, S. J.; Rack, P. D.; Baylor, L. R.; Cui, H.; Gardner, W. L. Appl. Phys. Lett. 2005, 86, 183106.
Brintlinger, T.; Fuhrer, M. S.; Melngailis, J.; Utke, I.; Bret, T.; Perentes, A.; Hoffmann, P. Abourida, M.; Doppelt, P. J. Vac. Sci. & Technol., B 2005, 23, 3174-3177.
Croitoru, M. D.; Bertsche, G.; Kern, D. R.; Burkhardt, C.; Bauerdick, S.; Sahakalkan, S.; Roth, S. J. Vac. Sci. & Technol., B 2005, 23, 2789-2792.
Lau, Y. M.; Chee, P. C.; Thong, J. T. L.; Ng, V. J. Vac. Sci. & Technol., A 2002, 20, 1295-1302.
Mukawa, T.; Okada, S.; Kobayashi, R.; Fujita, J.; Ishida, M.; Ichihashi, T.; Ochiai, Y.; Kaito, T.; Matsui, S. Jpn. J. Appl. Phys., Part 1 2005, 44, 5639-5641.
Liang, T.; Frendberg, E.; Lieberman, B.; Stivers, A. J. Vac. Sci. & Technol., B 2005, 23, 3101-3105.
Randolph, S. J.; Fowlkes, J. D.; Rack, P. D. Crit. Rev. Solid State Mater. Sci. 2006, 31, 55-89.
Utke, I.; Hoffmann, P.; Melngailis, J. J. Vac. Sci. & Technol., B 2008, 26, 1197-1276.
van Dorp, W. F.; Hagen, C. W. J. Appl. Phys. 2008, 104, 081301.
Thiberge, S.; Zik, O.; Moses, E. Rev. Sci. Instrum. 2004, 75, 2280-2289.
Botman, A.; Mulders, J. J. L.; Weemaes, R.; Mentink, S. Nanotechnology 2006, 17, 3779-3785.
Wang, S.; Sun, Y.-M.; Wang, Q.; White, J. M. J. Vac. Sci. & Technol., B 2004, 22, 1803-1806.
Langford, R. M.; Wang, T. X.; Ozkaya, D. Microelectron. Eng. 2007, 84, 784-788.
Lin, J. F.; Bird, J. P.; Rotkina, L.; Bennett, P. A. Appl. Phys. Lett. 2003, 82, 802-804.
Penate-Quesada, L.; Mitra, J.; Dawson, P. Nanotechnology 2007, 18, 215203.
Tao, T.; Ro, J. S.; Meingailis, J.; Xue, Z. L.; Kaesz, H. D. J. Vac. Sci. & Technol., B 1990, 8, 1826-1829.
Telari, K. A.; Rogers, B. R.; Fang, H.; Shen, L.; Weller, R. A.; Braski, D. N. J. Vac. Sci. & Technol., B 2002, 20, 590-595.

### BACKGROUND

Charged particle beam induced deposition and etching are widely used processes for the direct fabrication and modification of nanostructures. In these processes a focused electron or ion beam is used to locally induce a chemical reaction which either adds a material to a substrate (deposition) or removes material from a substrate (etching). Such processes are carried out in a vacuum chamber and the reactants are introduced as gases. These techniques are widely used to repair and modify the lithographic masks used in microelectronic manufacturing. In addition, they are used for rapid prototyping and modification of micro- and nanoscale devices and system. They are also used to interconnect chemically synthesized structures to external electrical contacts or circuits. Finally, these techniques provide a means of preparing thin samples for subsequent characterization and analysis.

Compared to many other micro- and nano-fabrication processes particle-beam induced etching and deposition have several distinct advantages. These processes directly pattern materials, alleviating the need for separate lithography, etching, and deposition steps. This permits rapid fabrication and modification of structures containing multiple materials without complex multistep processes. These processes also work well on either flat substrates or substrates with more complex topography. Finally, in contrast to self assembly processes, particle beam induced etching and deposition produce user designed micro- and nano-structures under computer control.

Currently, charged particle beam induced processes rely almost exclusively on gas-phase reactants and the electron or ion induce reactions between the gaseous reactant and a target substrate. Volatile reaction products lead to etching, while solid reaction products lead to deposition. Electron beam induced deposition has been widely investigated for nanoscale device prototyping (e.g. field emission arrays[2, 3], electrical connections to nanowires and nanotubes[9, 10], and patterned catalyst deposition[11, 12]) and for lithographic mask repair in integrated circuit manufacturing.[2, 5] Closely related processes have also been developed using focused ion beams and have been used for complex 3D nanofabrication, semiconductor mask repair, and microscopy sample preparation. The use of gas phase reactants allows deposition of certain metals, magnetic materials, semiconductors, and insulators with varying degrees of purity.[2] A more limited range of materials have been locally etched with a reactive gas and focused electron beam.[2, 13]

However, relying on gaseous reactants has many problems including (1) a limited selection of gas phase reactants for deposition and etching; (2) the use of many unstable, toxic, and expensive gaseous reactants; (3) the requirement of a volatile, as opposed to soluble, reaction product for etching; (4) deposition rates that are often limited by mass transport rather than beam current; (5) decomposition of precursors typically leads to high carbon or phosphorous contamination (60 to 80 at. % is typical); (6) deposition depends strongly on gas flux and direction; (7) insulating substrates often charge leading to pattern distortion;[4][6] and (8) It should also be noted that gaseous reactants need not be in the gas-phase at standard temperature and pressure. Volatile liquids can be introduced into the particle beam vacuum chamber in which they exist as a gas and then either adsorb or condense on the substrate prior to processing. In some cases these are referred to as liquid reactants or precursors. Nevertheless, these are not bulk liquids, they do not consist of solvents and solutes, and cannot be composed of multiple species. Thus, they differ markedly from the subject of the current invention in which we teach the use of bulk liquids, not thin adsorbed layers, that can consist of multiple solvents and solutes, and can have essentially any vapor pressure.

### BRIEF SUMMARY OF THE INVENTION

The invention disclosed here consists of a system and a method for charged particle beam induced deposition and etching using bulk liquid reactants instead of gaseous (or condensed gaseous) reactants. The liquids are separated from the particle beam vacuum chamber by a thin membrane that is essentially transparent to the charged particle beam. The substrate to be processed, which can include the membrane itself, is in contact with the bulk liquid and the particle beam is focused at the liquid-substrate interface. The particle beam induces a localized chemical reaction between the liquid reactant and the substrate. The liquid reactant can consist of one or more bulk liquids and any number of solutes.

The invention presented here addresses several limitations and solves several problems associated with the prior art of gaseous reactant based. (1) The use of bulk liquids with or without dissolved solids provides a much wide variety of reactants for particle beam induced processes. Thus, materials for which there are no known gas-phase reactants, such as silver, can be processed using liquid reactants. (2) Many gas-phase reactants used in the prior art are unstable, toxic, highly reactive with water and air, and difficult to manipulate. In contrast, many liquid-phase reactants can be stored for extended periods of time, are non-toxic or at least more easily handled in a safe manner. (3) Many gas-phase reactants are only used in a few chemical processes. This makes them less widely available and significantly more expensive than liquid reactants for the same processes.

(4) For standard particle-beam etch processes, a gaseous reactant must be identified that does not spontaneously etch the material in question, but that forms a volatile byproduct upon irradiation with the beam. In contrast, the use of liquid reactants taught here requires only a soluble (not a volatile) byproduct, and provides a wider range of effective etch chemistries. (5) Liquid phase processes (both deposition and etching) in conductive solutions eliminate charge build up on insulating substrates that can distort or deflect the electron beam during processing. Most gas-phase reactants do not promote charge dissipation and make processing of insulating substrates highly challenging. (6) Gas phase deposition processes frequently yield highly contaminated materials. In particular metalorganic gas-phase reactants produce high levels of carbon contamination. Fluoro- and chloro-phosphine based gaseous reactants can produce high levels of phosphorous contamination. In many cases these contaminants can reach 75 at. % of the deposit. In contrast, the bulk liquid processes taught here have been shown to yield up to 95 at. % purity deposits.

### BRIEF DESCRIPTION OF THE SEVERAL VIEWS OF THE DRAWING

The present invention may take form in various components and arrangements of components, and in various steps and arrangements of steps. The drawings are only for purposes of illustrating a preferred embodiment or embodiments and are not to be construed as limiting the present invention, wherein:

FIG. 1 depicts a liquid reactant separated from the vacuum chamber by a thin particle beam transparent membrane. The substrate to be processed is located on the side of the membrane opposite the incident beam and in contact with the liquid. The particle beam is focused at the liquid substrate interface to induce local deposition or etching.

FIG. 2 shows an electron micrograph of platinum nanostructures deposited from chloroplatinic acid by focusing an electron beam at the membrane substrate interface.

FIG. 3A shows an electron micrograph of gold nanostructures deposited from an aqueous solution of 100 μM chloroauric acid by focusing an electron beam at the membrane substrate interface.

FIG. 3B shows an electron micrograph of gold nanostructures deposited from aqueous solution of 100 μM sodium chloroaurate and 1 mM sodium sulfite.

FIG. 4 shows an electron micrograph of nickel nanostructures deposited from an aqueous solution of 1 mM nickel sulfate.

FIG. 5 shows an energy dispersive x-ray spectrum indicating that platinum deposition can exceed 90 at. % purity.

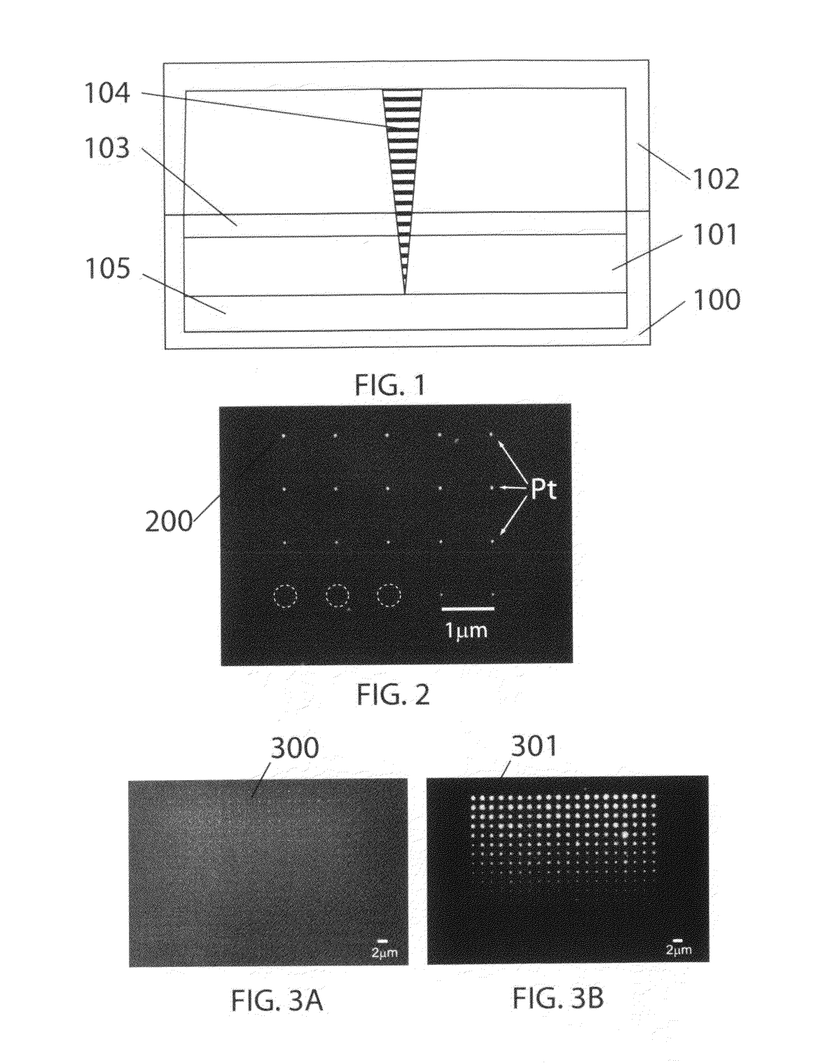

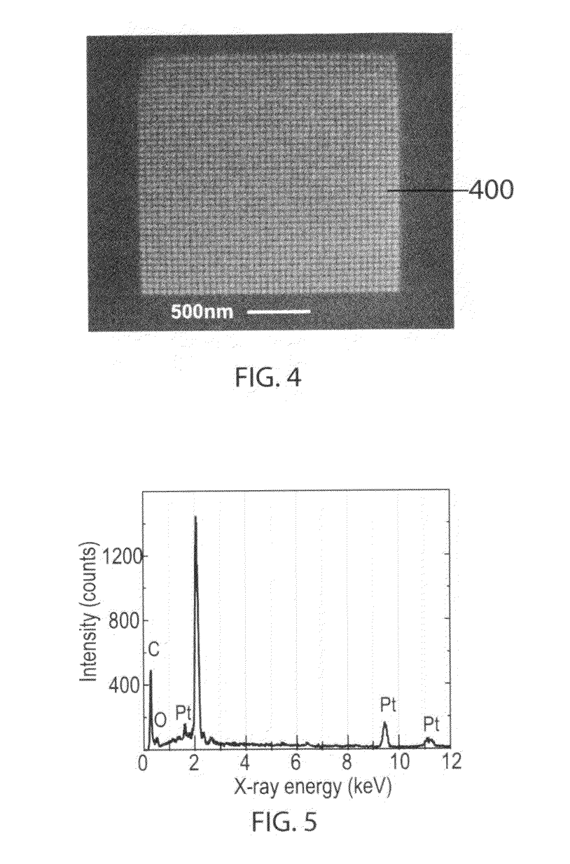

### DETAILED DESCRIPTION OF THE INVENTION

The details of one or more embodiments of the presently-disclosed subject matter are set forth in this document. Modifications to embodiments described in this document, and other embodiments, will be evident to those of ordinary skill in the art after a study of the information provided in this document. The information provided in this document, and particularly the specific details of the described exemplary embodiments, is provided primarily for clearness of understanding and no unnecessary limitations are to be understood there from. In case of conflict, the specification of this document, including definitions, will control.

Unless otherwise indicated, all numbers expressing quantities of ingredients, properties such as reaction conditions, and so forth used in the specification and claims are to be understood as being modified in all instances by the term “about”. Accordingly, unless indicated to the contrary, the numerical parameters set forth in this specification and claims are approximations that can vary depending upon the desired properties sought to be obtained by the presently-disclosed subject matter.

As used herein, the term “about,” when referring to a value or to an amount of mass, weight, time, volume, concentration or percentage is meant to encompass variations of in some embodiments±20%, in some embodiments±10%, in some embodiments±5%, in some embodiments±1%, in some embodiments±0.5%, and in some embodiments±0.1% from the specified amount, as such variations are appropriate to perform the disclosed method.

The presently-disclosed subject matter includes systems and methods for applying nanostructures to a substrate using a liquid reactant. The systems and methods of the presently disclosed subject matter are useful for prototyping and low-volume production of nanoscale devices for repair and modification of nanoscale masks and templates used in high-volume production. Use of the systems and methods of the presently-disclosed subject matter allow for efficient production of nanometer-scale structures composed of multiple materials.

In some embodiments of the presently-disclosed subject matter, a system for applying a nanostructure to a substrate using a liquid reactant includes a first chamber 100 for containing the liquid reactant 101, a second chamber 102 that is a vacuum chamber, a membrane 103 separating the first chamber and the second chamber; and means for producing a beam 104 for focusing through the second chamber at a liquid-substrate 105 interface, thereby applying the nanostructure to the substrate 105 at the liquid-substrate interface.

In some embodiments of the presently-disclosed subject matter, a method for applying a nanostructure to a substrate using a liquid reactant includes providing a first chamber 100, a second chamber 102, and a membrane 103 separating the first and second chambers, wherein the second chamber 102 is a vacuum chamber; providing the liquid precursor 101 in the first chamber 100; providing the substrate 105, such that a liquid-substrate interface is created; focusing a beam 104 through the second chamber 102 at the liquid-substrate interface, thereby applying the nanostructure to the substrate 105 at the liquid-substrate interface.

In some embodiments, applying the nanostructure to the substrate consists of depositing the nanostructure onto the substrate. In some embodiments, applying the nanostructure to the substrate consists of etching the nanostructure into the substrate. In some embodiments, the nanostructure is deposited using an electron-beam induced deposition (EBID). In some embodiments, the nanostructure is deposited using an ion beam induced deposition (IBID). In some embodiments, the nanostructure is etched using an electron-beam induced etching (EBIE). In some embodiments, the nanostructure is etched using an ion-beam induced etching (IBIE).

In some embodiments, the substrate is the membrane itself, such that the electron beam is focused at a liquid-membrane interface, thereby applying the nanostructure to the membrane at the liquid-membrane interface. In some embodiments the substrates is a semiconductor wafer and in some embodiments the substrate is a lithographic mask used in microelectronic manufacturing.

In some embodiments, the membrane is a polyimide membrane. In some embodiments, the membrane is a silicon nitride membrane. In some embodiments the membrane is a silicon membrane, and in some embodiments the membrane is a silicon oxide membrane. In all embodiments the membrane is essentially transparent to the particle beam. For practical beam energies from 1 keV to 300 keV this suggests a membrane thickness of 10 nm to 10000 nm depending on beam energy and charged particle type.

In some embodiments of the presently-disclosed subject matter, a system and method for depositing a nanostructure using a liquid reactant is provided. In some embodiments this reactant is an aqueous solution. In some embodiments, the aqueous solution contains metal ions or complex metal ions.

In some embodiments, the metal ions are chloroplatinate ions for the deposition of platinum nanostructures 200. In some embodiments, the chloroplatinate ions are introduced into solution from chloroplatinic acid at a concentration ranging from 1 μM to 100 mM. In other embodiments, the chloroplatinate ions are introduced from sodium chloroplatinate. In still other embodiments, other soluble platinum complex ions are used. In some embodiments the platinum purity can exceed 90 at.% as shown by the energy dispersive x-ray spectrum in FIG. 5.

In some embodiments, the liquid reactant is an aqueous solution containing chloroaurate ions for the deposition of gold nanostructures 300. The chloroaurate ions can be introduced using a concentration from 1 μM to 100 mM chloroauric acid, sodium chloroaurate, or other soluble chloroaurate compounds familiar to those skilled in the art. In some embodiments the gold purity can exceed 95 at.%.

In some embodiments, the liquid reactant is an aqueous solution containing disulfitoaurate ions for the deposition of gold nanostructures 301. The disulfitoaurate ions can be introduced using a solution sodium chloroaurate with concentration between 1 μM and 100 mM and sodium sulfite with concentration between 1 μM and 1 mM as long as the sodium sulfite concentration exceeds the sodium chloroaurate concentration by approximately seven to ten times. In some embodiments the gold purity from the disulfitoaurate complex can exceed 70 at.%. In a further embodiment cyanoaurate ions in aqueous solution are used for the deposition of gold.

In some embodiments the liquid reactant is an aqueous solution containing a chromium ion or complex ion suitable for the deposition of chromium or a chromium oxide. In some embodiments chromium ions include hexaquochromium (III), tetra-aquadichlorochromium (III), or other soluable chromium complex ions. In some embodiments the chromium complex ions are introduced in solution using chromium (III) chloride, chromium (III) sulfate, or other soluble chromium compounds. In some embodiments, the liquid reactant is an aqueous solution of chromium (III) chloride with concentration between 1 μM and 1 mM. In another embodiment, the liquid reactant is an aqueous solution of chromium (III) sulfate with concentration between 1 μM and 1 mM.

In some embodiments, the liquid reactant is an aqueous solution containing a nickel ion or complex ion suitable for the deposition of nickel nanostructures 400. The nickel ions can be introduced in solution using nickel chloride, nickel sulfate, or other soluble nickel compounds. In some embodiments, an aqueous solution containing nickel sulfate with concentration between 10 μM and 1 mM is used to produce nickel nanostructures 400.

In some embodiments the liquid reactant is an aqueous solution containing a silver ion or ionic complex suitable for the deposition of silver. This can be an aqueous solution containing silver, cyanoargentate, succinimidoargentate, or thiosulfatoargentate ions. The ions are introduced in solution using silver nitrate, sodium silver cyanide, potassium silver cyanide, or other soluble compounds of silver and its coordinating ligands.

In some embodiments, the liquid reactant is an aqueous solution containing two or more metal ions or ion complexes suitable for deposition of a metal alloy. Example alloys include gold silver alloy, an iron nickel alloy, and a platinum cobalt alloy.

In another embodiment, the liquid reactant is an aqueous solution containing one or more metal ions or complex ions and an agent suitable for capping the growth of nanoparticles. Such a technique allows the local deposition of nanoparticles of controlled size based on the electron-beam induced reduction of the metal ion. Possible capping agents include sodium citrate or cetyl trimethylammonium bromide.

In another embodiment the liquid reactant is an aqueous solution containing two or more compounds suitable for the deposition of a compound semiconductor. In one embodiment, the liquid reactant contains soluble compounds of cadmium and sulfur suitable for deposition of CdS. These could include cadmium sulfate and sodium thiosulfate. In addition soluable selenium compounds can be introduced for the deposition of CdSe.

In a further embodiment, the liquid reactant is an organic solvent or an ionic liquid with or without additional dissolved compounds. In some embodiments, the liquid reactant is a metal organic compound dissolved in the solvent. In a specific embodiment the compound is platinum (II) acetylacetonate and is used to deposit platinum. In an alternative embodiment, the compound is dimethyl gold acetylacetonate used for the deposition of gold.

In other embodiments, the liquid reactant is an organic solvent or ionic liquid with dissolved compounds of vanadium, titanium, aluminum, or other metals that cannot normally be deposited from aqueous solutions. Alternatively, the liquid reactant is an organic solvent or ionic liquid with dissolved compounds of silicon, germanium, or other semiconductors that cannot normally be deposited from aqueous solutions. In another embodiment, the liquid reactant is an organic solvent or ionic liquid with dissolved compounds suitable for the deposition of oxides or insulating materials. In a specific embodiment, the liquid reactant is an organic solution containing an alkoxide. In a more specific embodiment, the liquid reactant is tetraethoxysilane (TEOS) or an organic solution containing TEOS for the deposition of silicon oxides.

In other embodiments, the nanostructure is applied to the substrate by etching the nanostructure into the substrate. In some embodiments, the liquid reactant is an aqueous solution suitable for etching the substrate. In a specific embodiment, the liquid reactant is hydrochloric acid and the substrate is chromium, chromium oxide, or another material coated with chromium or chromium oxide. In another embodiment the liquid reactant is a solution containing hydrofluoric acid, sodium fluoride, potassium fluoride, or ammonium fluoride and the substrate is silicon, silicon dioxide, or a silica glass. In yet another embodiment, the liquid reactant is a fluorinated or chlorinated organic liquid and the substrate is silicon, silicon dioxide, or a silica glass. In a further embodiment the liquid reactant is a solution containing hydrogen peroxide and the substrate is a III-V semiconductor.

1. A system for applying a nanostructure to a substrate using a liquid reactant, comprising:
a first chamber for containing the liquid reactant,
a second chamber that is a vacuum chamber,
a membrane separating the first chamber and the second chamber; and
means for producing a beam for focusing through the second chamber at a liquid-substrate interface, applying the nanostructure to the substrate at the liquid-substrate interface.

2. The system of claim 1 wherein the membrane is a polyimide membrane, a silicon nitride membrane, a silicon membrane, or a silicon oxide membrane.

3. The system of claim 1 wherein the beam is an electron beam.

4. The system of claim 1 wherein the beam is an ion beam.

5. The system of claim 1 wherein the vacuum chamber pressure is variable.

6. The system of claim 1 wherein the beam energy is between 1 keV and 300 keV.

7. The system of claim 1 wherein the first chamber is connected to multiple liquid reservoirs to allow exchange and mixing of multiple liquids.

8. A method for applying a nanostructure to a substrate using a liquid reactant, comprising:
providing a first chamber, a second chamber, and a membrane separating the first and second chambers, wherein the second chamber is a vacuum chamber;
providing the liquid reactant in the first chamber;
providing the substrate, such that a liquid-substrate interface is created;
focusing a beam through the second chamber at the liquid-substrate interface, thereby applying the nanostructure to the substrate at the liquid-substrate interface.

9. The method of claim 8, wherein applying the nanostructure to the substrate is selected from:
etching the nanostructure into the substrate at the liquid-substrate interface using electron-beam induced etching (EBIE);
etching the nanostructure into the substrate at the liquid-substrate interface using ion beam induced etching (IBIE);
depositing the nanostructure onto the substrate at the liquid-substrate interface using electron-beam induced deposition (EBID); and
depositing the nanostructure onto the substrate at the liquid-substrate interface using ion-beam induced deposition (IBID).

10. The method of claim 8, wherein the membrane is a polyimide membrane, a silicon nitride membrane, a silicon membrane, or a silicon oxide membrane.

11. The method of claim 8, where the substrate is the membrane itself, such that the electron beam is focused through the second chamber at a liquid-membrane interface, thereby applying the nanostructure to the membrane at the liquid-membrane interface.

12. The method of claim 8, wherein the substrate is a semiconductor wafer.

13. The method of claim 8, wherein the substrate is a mask used for lithography in microelectronic manufacturing.

14. The method of claim 8, wherein the substrate is insulating and the liquid is used to dissipate charge that would otherwise accumulate when exposed to charged particle beams.

15. The method of claim 8, wherein applying the nanostructure to the substrate consists of depositing the nanostructure onto the substrate.

16. The method of claim 15, wherein the liquid reactant is an aqueous solution containing a metal ion or ion complex.

17. The method of claim 16 wherein the liquid reactant is an aqueous solution containing a platinum ion or complex ion suitable for the deposition of platinum.

18. The method of claim 17 wherein the liquid reactant is an aqueous solution containing chloroplatinate complex ions.

19. The method of claim 18 wherein the chloroplatinate ion is introduced into solution using chloroplatinic acid, sodium chloroplatinate, or other soluble platinum compound.

20. The method of claim 19 wherein the liquid reactant is a solution of chloroplatinic acid with concentrations between 10 μM and 100 mM.

21. The method of claim 20 wherein the purity of the platinum structure is 90 at.%.

22. The method of claim 15 wherein the liquid reactant is an aqueous solution containing a gold ion or complex ion suitable for the deposition of gold.

23. The method of claim 22 wherein the liquid reactant is an aqueous solution containing chloroaurate, disulfitoaurate, or cyanoaurate ions.

24. The method of claim 23 wherein the chloroaurate, disulfitoaurate, or cyanoaurate ions are introduced or produced from various soluble gold compounds and coordinating ligands.

25. The method of claim 24 wherein the liquid reactant is an aqueous solution of chloroauric acid with concentration between 1 μM and 100 mM.

26. The method of claim 25 wherein the purity of the gold structure is about 95 at.%.

27. The method of claim 24 wherein the liquid reactant is an aqueous solution of sodium chloroaurate with concentration between 1 μM and 100 mM.

28. The method of claim 24 wherein the liquid reactant is an aqueous solution of sodium chloroaurate with concentration between 1 μM and 100 mM and sodium sulfite with concentration between 1 μM and 1 mM.

29. The method of claim 28 wherein the purity of the gold structure is about 70 at.%.

30. The method of claim 15 wherein the liquid reactant is an aqueous solution containing a chromium ion or complex ion suitable for the deposition of chromium or a chromium oxide.

31. The method of claim 30 wherein the liquid reactant is an aqueous solution containing hexaquochromium (III), tetraaquadichlorochromium (III), or other soluble chromium complex ions.

32. The method of claim 31 wherein the chromium complex ions are introduced in solution using chromium (III) chloride, chromium (III) sulfate, or other soluble chromium compounds.

33. The method of claim 32 wherein the liquid reactant is an aqueous solution of chromium (III) chloride with concentration between 1 μM and 1 mM.

34. The method of claim 32 wherein the liquid reactant is an aqueous solution of chromium (III) sulfate with concentration between 1 μM and 1 mM.

35. The method of claim 15 wherein the liquid reactant is an aqueous solution containing a nickel ion or complex ion suitable for the deposition of nickel.

36. The method of claim 35 wherein the wherein the ions are introduced in solution using nickel chloride, nickel sulfate, or other soluble nickel compounds.

37. The method of claim 36 wherein the liquid reactant is an aqueous solution containing nickel sulfate with concentration between 10 μM and 1 mM.

38. The method of claim 15 wherein the liquid reactant is an aqueous solution containing a silver ion or ionic complex suitable for the deposition of silver.

39. The method of claim 38 wherein the liquid reactant is an aqueous solution containing silver, cyanoargentate, succinimidoargentate, or thiosulfatoargentate ions.

40. The method of claim 29 wherein the wherein the ions are introduced in solution using silver nitrate, sodium silver cyanide, potassium silver cyanide, or other soluble compounds of silver and its coordinating ligands.

41. The method of claim 15 wherein the liquid reactant is an aqueous solution containing two or more metal ions or ion complexes suitable for deposition of a metal alloy.

42. The method of claim 41 wherein the metal alloy is a gold silver alloy, an iron nickel alloy, or a platinum cobalt alloy.

43. The method of claim 15 wherein the liquid reactant is an aqueous solution containing one or more metal ions or complex ions and an agent suitable for capping the growth of nanoparticles.

44. The method of claim 43 wherein the capping agent is sodium citrate or cetyl trimethylammonium bromide.

45. The method of claim 15 wherein the liquid reactant is an aqueous solution containing two or more compounds suitable for the deposition of a compound semiconductor.

46. The method of claim 45, wherein the liquid reactant contains soluble compounds of cadmium and sulfur suitable for deposition of CdS.

47. The method of claim 46, wherein the liquid reactant is an aqueous solution of cadmium sulfate and sodium thiosulfate.

48. The method of claim 45 wherein the liquid reactant contains soluble compounds of cadmium and selenium suitable for deposition of CdSe.

49. The method of claim 15 wherein the liquid reactant is an organic solvent or an ionic liquid with or without additional dissolved compounds.

50. The method of claim 49 wherein the liquid reactant is a metal organic compound dissolved in the solvent.

51. The method of claim 50 wherein platinum (II) acetylacetonate is the metal organic compound and is used to deposit platinum.

52. The method of claim 50 wherein dimethyl gold acetylacetonate is the metal organic compound.

53. The method of claim 49 wherein the liquid reactant is an organic solvent or ionic liquid with dissolved compounds of vanadium, titanium, aluminum, or other metals that cannot normally be deposited from aqueous solutions.

54. The method of claim 49 wherein the liquid reactant is an organic solvent or ionic liquid with dissolved compounds of silicon, germanium, or other semiconductors that cannot normally be deposited from aqueous solutions.

55. The method of claim 49 wherein the liquid reactant is an organic solvent or ionic liquid with dissolved compounds suitable for the deposition of oxides or insulating materials.

56. The method of claim 55 wherein the liquid reactant is an organic solution containing an alkoxide.

57. The method of claim 56 wherein the liquid reactant is tetraethoxysilane (TEOS) or an organic solution containing TEOS for the deposition of silicon oxides.

58. The method of claim 8, wherein applying the nanostructure to the substrate consists of etching the nanostructure into the substrate

59. The method of claim 58 wherein the liquid reactant is an aqueous solution suitable for etching the substrate.

60. The method of claim 59 wherein the liquid reactant is hydrochloric acid and the substrate is chromium, chromium oxide, or another material coated with chromium or chromium oxide.

61. The method of claim 59 wherein the liquid reactant is a solution containing hydrofluoric acid, sodium fluoride, potassium fluoride, or ammonium fluoride and the substrate is silicon, silicon dioxide, or a silica glass.

62. The method of claim 59 wherein the liquid reactant is a fluorinated or chlorinated organic liquid and the substrate is silicon, silicon dioxide, or a silica glass.

63. The method of claim 59 wherein the liquid reactant is a solution containing hydrogen peroxide and the substrate is a III-V semiconductor.
